(19) United States
(12) Patent Application Publication
(10) Pub. No.: US 2026/0327792 A1
(43) Pub. Date: Oct. 22, 2026

(54) SUBSTRATE PROCESSING APPARATUS INCLUDING SPRAY PIPELINE

(71) Applicant: SAMSUNG ELECTRONICS CO., LTD., Suwon-si (KR)

(72) Inventor: JONG-RIM KIM, Suwon-si (KR)

(73) Assignee: SAMSUNG ELECTRONICS CO., LTD., Suwon-si (KR)

(21) Appl. No.: 19/572,292

(22) Filed: Mar. 19, 2026

(30) Foreign Application Priority Data
Apr. 21, 2025 (KR) 10-2025-0051897

(51) Int. Cl. C23C 16/44

(52) U.S. Cl. CPC C23C 16/4404; C23C 16/4409

(57) ABSTRACT

A substrate processing apparatus may include: a process tube including an opened lower end; a sealing plate at a lower side of the process tube; a boat on an upper side of the sealing plate in a first direction, the boat configured to accommodate a plurality of substrates; at least one sealing ring connected to an upper surface of the sealing plate; and a spray pipeline on the upper surface of the sealing plate. The spray pipeline may include at least one spray opening that faces the at least one sealing ring, and the spray pipeline may be configured to spray a fluid, via the at least one spray opening, towards the at least one sealing ring.

### CROSS-REFERENCE TO RELATED APPLICATIONS

This application claims priority under 35 U.S.C. § 119 to Korean Patent Application No. 10-2025-0051897, filed on Apr. 21, 2025, in the Korean Intellectual Property Office, the disclosure of which is incorporated by reference herein in its entireties.

### BACKGROUND

### 1. Field

The disclosure relates to a substrate processing apparatus, and more particularly, relate to a substrate processing apparatus that includes a spray pipeline having a spray opening that faces a sealing ring.

### 2. Description of Related Art

A semiconductor element may be manufactured through various processes. For example, a semiconductor element may be manufactured by using processes that include a photolithography process, an etching process, an ion implantation process, a polishing process, and a deposition process. The deposition process may be performed to form a specific film on a surface of a substrate. For example, the deposition process may be a chemical vapor deposition (CVD) process or an atomic layer deposition (ALD) process. A process tube may be sealed during the deposition process. If the process tube is not sealed, defects in the deposition process may be caused. Meanwhile, the process tube may not be sealed due to by-products on a sealing ring. Accordingly, various methods for minimizing by-products on the sealing ring are being researched.

### SUMMARY

According to an aspect of the disclosure, a substrate processing apparatus that may minimize by-products on a sealing ring may be provided.

According to an aspect of the disclosure, a substrate processing apparatus may include: a process tube including an opened lower end; a sealing plate at a lower side of the process tube; a boat on an upper side of the sealing plate in a first direction, the boat configured to accommodate a plurality of substrates; at least one sealing ring connected to an upper surface of the sealing plate; and a spray pipeline on the upper surface of the sealing plate. The spray pipeline may include at least one spray opening that faces the at least one sealing ring, and the spray pipeline may be configured to spray a fluid, via the at least one spray opening, towards the at least one sealing ring.

According to an aspect of the disclosure, a substrate processing apparatus may include: a process tube including an opened lower end; a sealing plate at a lower side of the process tube; a boat on an upper side of the sealing plate; at least one sealing ring connected to an upper surface of the sealing plate; and a gas spraying device including a spray pipeline, the spray pipeline being on the upper surface of the sealing plate. The gas spraying device may be configured to spray purge gas toward the at least one sealing ring through the spray pipeline.

According to an aspect of the disclosure, a substrate processing apparatus may include: a process tube including an opened lower end; a sealing plate at a lower side of the process tube; a boat on an upper side of the sealing plate, the boat configured to accommodate a plurality of substrates; a heat absorbing material between the sealing plate and the boat, the heat absorbing material configured to regulate a temperature of the process tube; a protection plate between the sealing plate and the heat absorbing material, the protection plate configured to protect the sealing plate from heat; at least one actuator configured to vertically move the sealing plate; at least one sealing ring connected to an upper surface of the sealing plate; and a spray pipeline on the upper surface of the sealing plate. The spray pipeline may include at least one spray opening that faces the at least one sealing ring, and the spray pipeline is configured to spray a fluid, via the at least one spray opening, towards the at least one sealing ring.

### BRIEF DESCRIPTION OF DRAWINGS

The above and other aspects and features of the disclosure will become apparent by describing in detail embodiments thereof with reference to the accompanying drawings.

FIG. 1 is a cross-sectional view schematically illustrating a substrate processing apparatus in a first state according to an embodiment of the disclosure;

FIG. 2 is an enlarged cross-sectional view of an area S1 of FIG. 1;

FIG. 3 is a cross-sectional view schematically illustrating a substrate processing apparatus in a second state according to an embodiment of the disclosure;

FIG. 4 is an enlarged cross-sectional view of an area S2 of FIG. 3;

FIG. 5 is a plan view illustrating a portion of a substrate processing apparatus according to an embodiment of the disclosure;

FIG. 6 is a perspective view illustrating a portion of a substrate processing apparatus according to an embodiment of the disclosure;

FIG. 7 is an enlarged perspective view of an area S3 of FIG. 6;

FIG. 8 is a perspective view illustrating a spray pipeline and a vertical pipeline of a substrate processing apparatus according to an embodiment of the disclosure;

FIG. 9 is a perspective view illustrating a spray pipeline and a vertical pipeline of a substrate processing apparatus according to an embodiment of the disclosure;

FIG. 10 is a cross-sectional view schematically illustrating a substrate processing apparatus in a first state according to an embodiment of the disclosure;

FIG. 11 is a cross-sectional view schematically illustrating a substrate processing apparatus in a second state according to an embodiment of the disclosure;

FIG. 12 is a cross-sectional view schematically illustrating a substrate processing apparatus in a first state according to an embodiment of the disclosure; and

FIG. 13 is a cross-sectional view schematically illustrating a substrate processing apparatus in a second state according to an embodiment of the disclosure.

### DETAILED DESCRIPTION

Hereinafter, non-limiting example embodiments of the disclosure will be described clearly and in detail with reference to the accompanying drawings.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

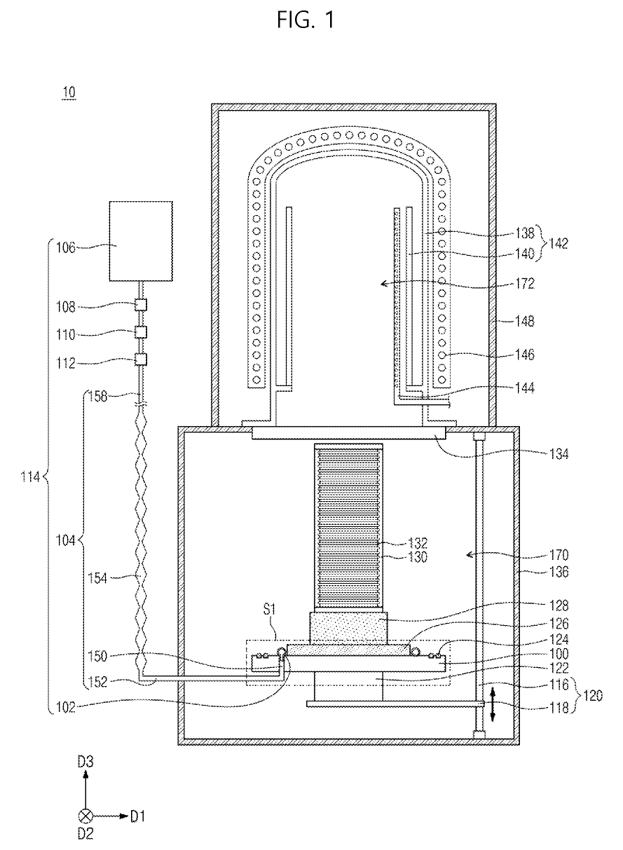

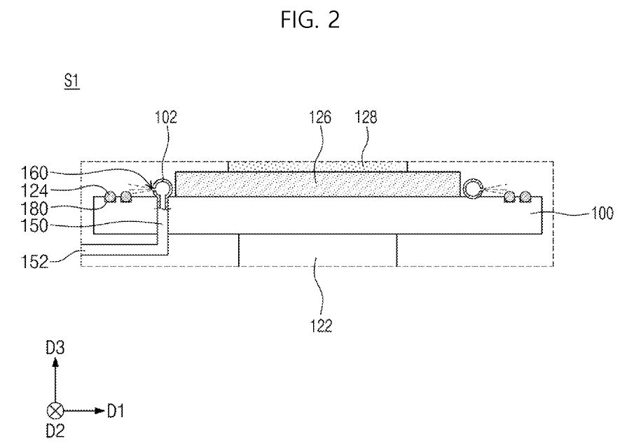

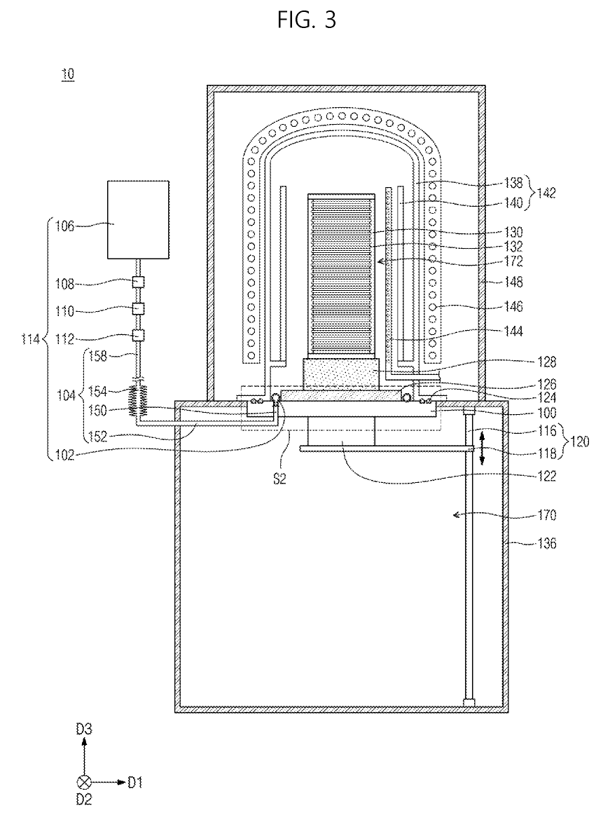

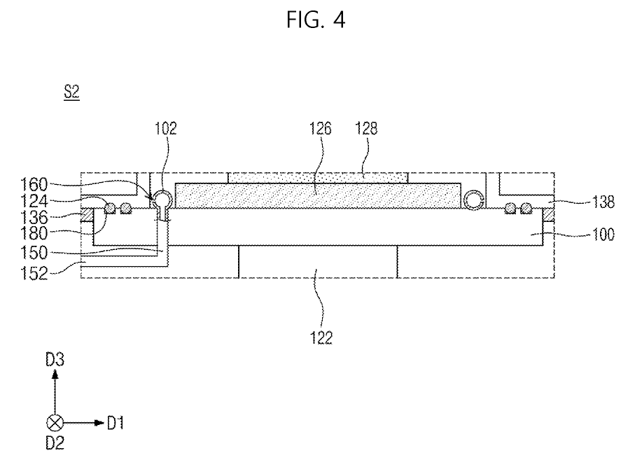

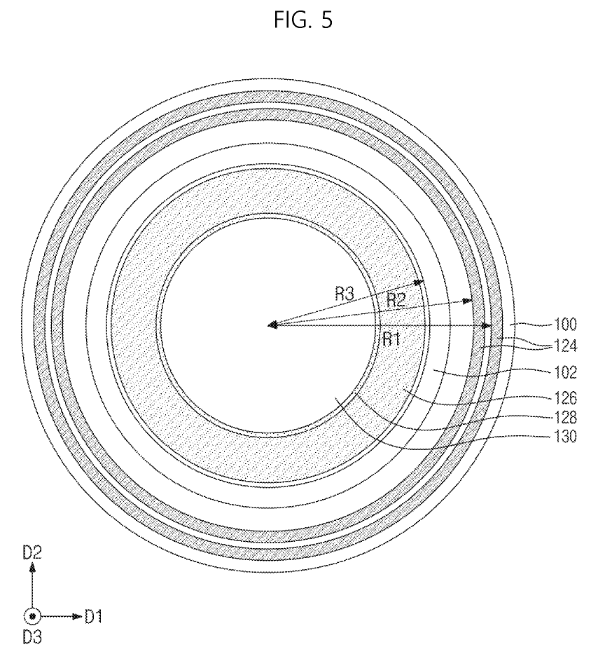

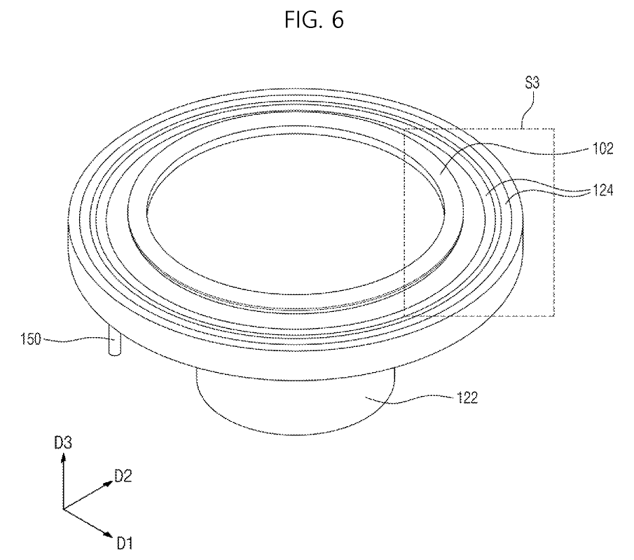

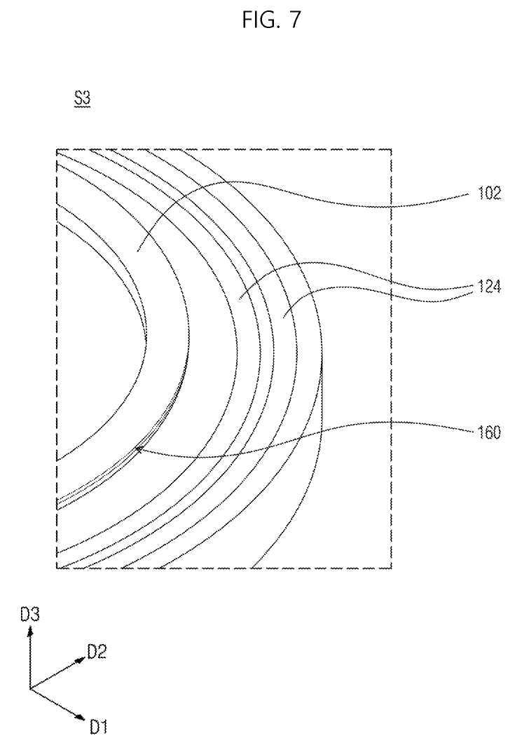

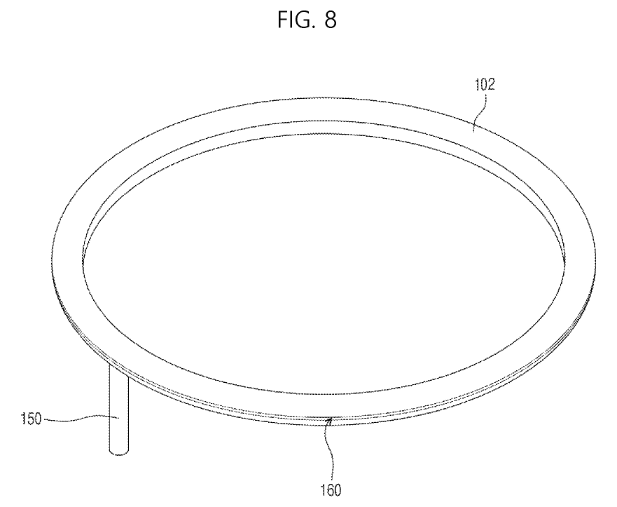

FIG. 1 is a cross-sectional view schematically illustrating a substrate processing apparatus in a first state according to an embodiment of the disclosure. FIG. 2 is an enlarged cross-sectional view of an area S1 of FIG. 1. FIG. 3 is a cross-sectional view schematically illustrating a substrate processing apparatus in a second state according to an embodiment of the disclosure. FIG. 4 is an enlarged cross-sectional view of an area S2 of FIG. 3. FIG. 5 is a plan view illustrating a portion of a substrate processing apparatus according to an embodiment of the disclosure. FIG. 6 is a perspective view illustrating a portion of a substrate processing apparatus according to an embodiment of the disclosure. FIG. 7 is an enlarged perspective view of area S3 of FIG. 6. FIG. 8 is a perspective view illustrating a spray pipeline and a vertical pipeline of a substrate processing apparatus according to an embodiment of the disclosure.

Referring to FIGS. 1-8, a substrate processing apparatus 10 according to an embodiment of the disclosure may include a load lock chamber 136, a shutter 134, a process tube 142, a process nozzle 144, a heating device 146, a cover 148, a sealing plate 100, a boat 130, a sealing ring 124, a gas spraying device 114 (e.g., a gas sprayer), a temperature maintenance device 128 (e.g., a heat absorbing material), a protection plate 126, a base 122, and a vertical driving device 120. The gas spraying device 114 may include a spray pipeline 102, a connection pipeline 104, a gas storage 106, a regulator 108, a pressure sensor 110, and a gas valve 112.

In some embodiments, the substrate processing apparatus 10 may be an apparatus for performing a deposition process. For example, the substrate processing apparatus 10 may be an apparatus for performing a chemical vapor deposition (CVD) process or an atomic layer deposition (ALD) process. That is, the substrate processing apparatus 10 may deposit a specific film on a surface of a substrate 132, and a material of the specific film may be various. The substrate 132 may be a semiconductor substrate for manufacturing a semiconductor element, but embodiments of the disclosure are not limited thereto.

The substrate processing apparatus 10 may be in a first state or a second state. The first state may be a state in which the boat 130 is outside the process tube 142. In other words, the first state may be a state, in which the boat 130 is unloaded from the process tube 142. When the substrate processing apparatus 10 is in the first state, the boat 130 may be located at a lower side of the process tube 142. The second state may be a state in which the sealing plate 100 closes a lower end of the process tube 142 and the boat 130 is located in an interior of the process tube 142. That is, the second state may be a state, in which the boat 130 is loaded in the process tube 142 and an interior space of the process tube 142 is closed (e.g., sealed) by the sealing plate 100.

The load lock chamber 136 may be disposed on a lower side of the process tube 142. The load lock chamber 136 may have a sealed space 170. For example, the load lock chamber 136 may include a first bottom part, a first wall part that extends upward from a periphery of the first bottom part, and a first ceiling part that overlaps with the first bottom part. A periphery of the first ceiling part may be connected to the first wall part. The first bottom part, the first wall part, and the first ceiling part of the load lock chamber 136 may define the sealed space 170. The first ceiling part may have an opening that passes through a central portion thereof.

As illustrated in FIG. 1, the shutter 134 may be mounted on the opening of the first ceiling part of the load lock chamber 136. The shutter 134 may open and close the opening of the first ceiling part. The sealed space 170 of the load lock chamber 136 may communicate with a processing space 172 of the process tube 142 when the shutter 134 is opened.

A substrate port may be provided at a portion of the first wall part of the load lock chamber 136, and an opening/closing device may be mounted on the substrate port. The substrate port may be opened and closed by the opening/closing device. For example, the opening/closing device may include at least one actuator that is configured to open and/or close the substrate port. In some embodiments, the substrate 132 may be moved into the boat 130 in the load lock chamber 136 through the substrate port, or may be moved from the boat 130 in the load lock chamber 136 to an outside of the load lock chamber 136. In some embodiments, the boat 130 that accommodates a plurality of substrates 132 may be moved into the load lock chamber 136 through the substrate port, or may be moved to an outside of the load lock chamber 136 from the sealed space 170 of the load lock chamber 136. The substrate 132 and/or the boat 130 may be moved through the substrate port by a separate transfer device, such as a robot arm. When the substrate 132 and/or the boat 130 is moved through the substrate port, the shutter 134 may close the opening of the first ceiling part of the load lock chamber 136. In other words, when the substrate 132 and/or the boat 130 is moved through the substrate port, a processing space 172 of the process tube 142 may be in a sealed state.

A vacuum pump and a gas injection pipeline may be connected to the load lock chamber 136. The vacuum pump may be configured to exhaust air from the load lock chamber 136 to form a vacuum state in the sealed space 170. The gas injection pipeline may be configured to inject an inert gas (e.g., nitrogen) into the load lock chamber 136 to form an atmospheric pressure state in the sealed space 170.

The process tube 142 may be provided on the load lock chamber 136 and may be coupled to the first ceiling part of the load lock chamber 136. The processing space 172 may be formed in an interior of the process tube 142. The substrate 132 may be processed in the processing space 172. The process tube 142 may have the opened lower end. In some embodiments, as illustrated in FIG. 1, the process tube 142 may include an outer tube 138 and an inner tube 140. Each of the outer tube 138 and the inner tube 140 may have a cylindrical shape that extends in a third direction D3. The third direction D3 may be a direction that is perpendicular to the first bottom part of the load lock chamber 136. The outer tube 138 may have a second wall part that extends upward from a coupling part coupled to the first ceiling part of the load lock chamber 136, and a second ceiling part that overlaps with the first bottom part of the load lock chamber 136. The second ceiling part may have a dome shape. A height of the second ceiling part may be higher than a level of the first ceiling part of the load lock chamber 136. The outer tube 138 may have an open lower end. The outer tube 138 may surround the inner tube 140. More specifically, the inner tube 140 may be located in the outer tube 138, and may be located to be spaced apart from the outer tube 138. The inner tube 140 may have a third wall part. Each of an upper end and a lower end of the inner tube 140 may be opened. A lower end between the outer tube 138 and the inner tube 140 may be sealed. The outer tube 138 and the inner tube 140 may be formed of quartz and/or silicon carbide (SiC), but embodiments of the disclosure are not limited thereto.

The process nozzle 144 may be provided in the inner tube 140. The process nozzle 144 may be configured to supply a process gas into the processing space 172. The process nozzle 144 may have a plurality of process gas spray openings. As illustrated in FIG. 1, the process nozzle 144 may extend to an outside of the outer tube 138, and may be connected to a processed gas supply. The deposition process may be performed in the processing space 172 of the substrate processing apparatus 10 in the second state. During the deposition process, the processing gas may be supplied into the processing space 172 through the process nozzle 144. As a result, the specific film may be formed on surfaces of the substrates 132.

The heating device 146 may be disposed to surround an outer surface of the second wall part of the outer tube 138 and the second ceiling part of the outer tube 138. The heating device 146 may be configured to heat the processing space 172 to a specific temperature. In some embodiments, the heating device 146 may include a plurality of heating wires that are connected to each other in parallel. Accordingly, the processing space 172 may be selectively heated depending on areas, and when a temperature of a specific area is lower than a temperature of another area, the specific area may be heated more than the other area.

The cover 148 may be disposed outside the heating device 146. The cover 148 may surround the heating device 146. The cover 148 may prevent heat generated from the heating device 146 that is heated to a high temperature from being lost to the outside, so that energy efficiency may be increased. In addition, the cover 148 may prevent other portions of the substrate processing apparatus 10 from being damaged by the heat of the heating device 146.

The sealing plate 100 may be provided at a lower side of the process tube 142. The sealing plate 100 may have a circular shape when viewed in a plan view. The sealing plate 100 may be moved vertically. As illustrated in FIG. 1, the sealing plate 100 of the substrate processing apparatus 10 in the first state may be lifted to provide the boat 130 in the process tube 142 and to seal a lower end of the process tube 142. As illustrated in FIG. 3, the sealing plate 100 of the substrate processing apparatus 10 in the second state may be lowered to provide the boat 130 at a lower side of the process tube 142.

The boat 130 may be provided on an upper side of the sealing plate 100. The boat 130 may be configured to accommodate the plurality of substrates 132. The boat 130 may include an upper plate and a lower plate that is disposed to be spaced apart from the upper plate. In addition, the boat 130 may further include vertical support parts that connect the upper plate and the lower plate. The vertical support parts may be arranged in a lengthwise direction of the vertical support parts, and may have a plurality of substrate accommodating recesses that are spaced apart from each other. The plurality of substrate accommodating recesses may be configured to accommodate the substrates 132, respectively. The upper plate and the lower plate may have a circular shape when viewed in a plan view. Accordingly, the boat 130 may have a circular shape when viewed in a plan view.

At least one sealing ring 124 may be coupled to an upper surface of the sealing plate 100. More specifically, at least one sealing ring 124 may be coupled to a periphery of the upper surface of the sealing plate 100. Sealing rings 124 that are coupled to the periphery of the upper surface of the sealing plate 100 may have a circular ring shape when viewed in a plan view. As illustrated in FIG. 1, the at least one sealing ring 124 may be two. However, embodiments of the disclosure are not limited thereto. In some embodiments, the at least one sealing ring 124 may be one or three or more. In some embodiments, the sealing plate 100 may have recesses 180 that are recessed downward from the upper surface of the sealing plate 100. The sealing rings 124 may be coupled to the recesses 180, respectively. The sealing rings 124 may be closely attached to a contact surface when compressed. Accordingly, the sealing rings 124 may provide an effective sealing function. In some embodiments, the sealing rings 124 may be O-rings. The sealing rings 124 may be formed of a material (e.g., perfluoroelastomer and/or silicone) having elasticity, heat resistance, and chemical resistance.

In the first state, the sealing plate 100 of the substrate processing apparatus 10 may be lowered to provide the boat 130 at a lower side of the process tube 142. In this case, a lower portion of each of the sealing rings 124 may be located in an interior of a corresponding recess 180, and an upper portion of each of the sealing rings 124 may protrude above the corresponding recess 180. In other words, an upper surface of each of the sealing rings 124 may be higher than the upper surface of the sealing plate 100.

In the second state, the sealing plate 100 of the substrate processing apparatus 10 may be lifted to provide the boat 130 in the process tube 142. In this case, as illustrated in FIG. 4, the sealing rings 124 may be compressed. In some embodiments, a lower end of the outer tube 138 may include a portion that extends flat in a first direction D1. The first direction D1 may be parallel to the bottom part of the load lock chamber 136. In the second state, the sealing rings 124 of the substrate processing apparatus 10 may contact a flatly extended portion of a lower end of the outer tube 138, and may be closely attached to the flatly extended portion. In this case, the processing space 172 in the process tube 142 may be sealed by the sealing plate 100 that closes the lower end of the process tube 142, and the sealing rings 124 that contact the lower end of the outer tube 138.

The gas spraying device 114 may be configured to spray a purge gas (that may be referred to as gas in the present specification) toward the sealing rings 124 through the spray pipeline 102. More specifically, the gas spraying device 114 may be configured to spray the purge gas toward the sealing rings 124 through the spray pipeline 102 when the sealing plate 100 is lowered to provide the boat 130 at a lower side of the process tube 142.

The spray pipeline 102 of the gas spraying device 114 may be coupled to an upper surface of the sealing plate 100. The spray pipeline 102 may have a closed loop shape that surrounds the boat 130 when viewed in a plan view. In some embodiments, the spray pipeline 102 may have a ring shape that surrounds the boat 130 when viewed in a plan view. More specifically, as illustrated in FIG. 5, the spray pipeline 102 may have a ring shape that surrounds the boat 130 when viewed in a plan view, and may be disposed between the boat 130 and the sealing rings 124. In addition, a center of the sealing plate 100 may coincide with centers of the sealing rings 124 and a center of the spray pipeline 102. As a result, distances R1 and R2 of the sealing rings 124 from the center of the sealing plate 100 may be greater than a distance R3 of the spray pipeline 102 from the center of the sealing plate 100.

In the first state, the sealing plate 100 of the substrate processing apparatus 10 may be lowered to be provided at a lower side of the load lock chamber 136, and the spray pipeline 102 coupled to the sealing plate 100 may be located in the load lock chamber 136. In the second state, the sealing plate 100 of the substrate processing apparatus 10 may be lifted to seal a lower end of the process tube 142. In this case, the spray pipeline 102 may be located in the process tube 142. In some embodiments, the spray pipeline 102 may include a corrosion-resistant metal alloy (e.g., a nickel alloy).

The spray pipeline 102 may have a spray opening 160 that faces the sealing rings 124. Referring to FIGS. 6-8, the spray opening 160 may have a single slit shape that extends along the spray pipeline 102, and a total length of the spray opening 160 may be substantially the same as a total length of the spray pipeline 102. For example, the total length of the spray opening 160 may be in a range of 90% to 100% of a total length of the spray pipeline 102. For example, the spray opening 160 may at least partially surround the protection plate 126 in horizontal directions (e.g., the first direction D1 and/or the second direction D2), along a circumference of the protection plate 126.

The gas storage 106 of the gas spraying device 114 may store the purge gas. Referring to FIGS. 1 and 3, the gas storage 106 may be disposed outside the load lock chamber 136.

The connection pipeline 104 of the gas spraying device 114 may connect the gas storage 106 and the spray pipeline 102. The connection pipeline 104 may include a vertical pipeline 150, a first pipeline 152, a variable length pipeline 154, and a second pipeline 158. Referring to FIGS. 1-4, one end of the vertical pipeline 150 may be coupled to the spray pipeline 102 and may pass through the sealing plate 100. One end of the first pipeline 152 may be coupled to an opposite end of the vertical pipeline 150. The first pipeline 152 may extend to the outside of the load lock chamber 136. One end of the variable length pipeline 154 may be coupled to an opposite end of the first pipeline 152. One end of the second pipeline 158 may be coupled to an opposite end of the variable length pipeline 154, and an opposite end of the second pipeline 158 may be coupled to the gas storage 106.

A length of the variable length pipeline 154 may be variable. In some embodiments, as illustrated in FIG. 1, the variable length pipeline 154 may have a length that is extendable or contractible in a bellows manner. More specifically, the variable length pipeline 154 in the bellows manner may include a corrugated structure, and the corrugated structure may be extended or contracted so that a length thereof may be variable. However, embodiments of the disclosure are not limited thereto. The variable length pipeline 154 may have a length that is extendable or contractible in a telescopic manner. The variable length pipeline 154 in the telescopic manner may include a plurality of pipes that may overlap with each other or be connected to each other. More specifically, the variable length pipeline 154 in the telescopic manner may have a length that is extended as the plurality of pipes move away from each other, and may have its length that is contracted as the plurality of pipes overlap with each other. The variable length pipeline 154 in the telescopic manner may have a plurality of connection joints when the plurality of pipes are connected to each other. Each of the plurality of connection joints may have a gas leakage prevention packing for sealing an interior of the variable length pipeline 154 in the telescopic manner.

In some embodiments, as illustrated in FIGS. 1 and 3, the variable length pipeline 154 of the substrate processing apparatus 10 in the first state may be extended, and the variable length pipeline 154 of the substrate processing apparatus 10 in the second state may be contracted. However, the embodiments of the disclosure are not limited thereto. The extension and contraction of the variable length pipeline 154 may be determined depending on a distance between the spray pipeline 102 and the gas storage 106. The variable length pipeline 154 may be extended when the distance between the spray pipeline 102 and the gas storage 106 increases, and may be contracted when the distance between the spray pipeline 102 and the gas storage 106 decreases.

The regulator 108 and the gas valve 112 may be coupled to the connection pipeline 104. More specifically, the regulator 108 and the gas valve 112 may be coupled to the second pipeline 158 of the connection pipeline 104. The regulator 108 may be configured to regulate a pressure of the purge gas in the connection pipeline 104. The gas valve 112 may be configured to control inflow and outflow of the purge gas in the connection pipeline 104. The gas spraying device 114 may further include a gas filter and a pressure sensor 110. The gas filter may be coupled to the connection pipeline 104 and may be configured to filter out foreign substances in the purge gas. The pressure sensor 110 may be coupled to the connection pipeline 104. More specifically, a distance between the pressure sensor 110 and the gas storage 106 may be greater than a distance between the regulator 108 and the gas storage 106. For example, the pressure sensor 110 may be connected to a portion of the second pipeline 158 that is downstream of another portion of the second pipeline 158 to which the regulator 108 is connected. The pressure sensor 110 may be configured to measure a pressure of the purge gas that has passed through the regulator 108. The gas spraying device 114 may further include a controller that is configured to control the regulator 108 and the gas valve 112. In addition, the controller may be configured to display a pressure of the purge gas measured by the pressure sensor 110. For example, the controller may include at least one processor and memory storing computer instructions. The computer instructions, when executed by the at least one processor, may be configured to cause the controller to perform its functions.

The temperature maintenance device 128 may be provided between the sealing plate 100 and the boat 130. In some embodiments, the heating device 146 may be configured to surround an outer surface of the second wall part of the outer tube 138 and the second ceiling part of the outer tube 138. Accordingly, a temperature of lower portions of the outer tube 138 and the inner tube 140 may be lower than a temperature of upper portions of the outer tube 138 and the inner tube 140. The temperature maintenance device 128 of the substrate processing apparatus 10 in the second state may be configured to absorb the heat generated from the heating device 146. In this case, a temperature of the lower portions of the outer tube 138 and the inner tube 140 may be maintained substantially the same as a temperature of the upper portions of the outer tube 138 and the inner tube 140 by the temperature maintenance device 128. For example, the temperature maintenance device 128 may include a thermally conductive material, and may be configured to regulate a temperature of the process tube 142.

The protection plate 126 may be provided between the sealing plate 100 and the temperature maintenance device 128, and may be configured to protect the sealing plate 100 from the heat. The temperature maintenance device 128 and the protection plate 126 may have a circular shape when viewed in a plan view. As illustrated in FIG. 5, centers of the temperature maintenance device 128 and the protection plate 126 may coincide with the center of the sealing plate 100.

A base 122 may be coupled to a lower surface of the sealing plate 100. The base 122 may include a rotation shaft and a rotation motor configured to rotate the rotation shaft in an interior thereof. The rotation shaft may extend to pass through the centers of the sealing plate 100, the protection plate 126, and the temperature maintenance device 128, and may be coupled to a lower surface of the lower plate of the boat 130. The boat 130 may be rotated by the rotation shaft and the rotation motor of the base 122.

The vertical driving device 120 may include a vertical part 116 and a support part 118 may be provided in the load lock chamber 136. The vertical part 116 of the vertical driving device 120 may extend in the third direction D3. One end of the support part 118 may be connected to the vertical part 116, and the support part 118 may be moved vertically along a direction, in which the vertical part 116 extends. An upper surface of the support part 118 may be coupled to a lower surface of the base 122. Accordingly, the vertical driving device 120 including the vertical part 116 and the support part 118 may be configured to move the sealing plate 100 vertically. The vertical driving device 120 of the substrate processing apparatus 10 in the first state may lower the sealing plate 100, and the boat 130 may be located on a lower side of the process tube 142. The vertical driving device 120 of the substrate processing apparatus 10 in the second state may lift the sealing plate 100, and the boat 130 may be located in the process tube 142. According to some embodiments, the vertical driving device 120 may further include at least one actuator (e.g., a motor) that is configured to vertically move the sealing plate 100 by moving the support part 118 relative to the vertical part 116 or by moving the support part 118 and the vertical part 116 together.

According to the above-described embodiments, the gas spraying device 114 may spray the purge gas toward the sealing rings 124 through the spray pipeline 102. More specifically, the gas spraying device 114 may spray the purge gas toward the sealing rings 124 through the spray pipeline 102 after the sealing plate 100 is lowered to provide the boat 130 at a lower side of the process tube 142.

The deposition process may be performed in the processing space 172 of the substrate processing apparatus 10 in the second state. As a result, the specific film may be formed on surfaces of the substrates 132. In this case, by-products may be generated on inner surfaces of the inner tube 140 and the outer tube 138. Subsequently, when the sealing plate 100 is lowered to unload the boat 130 from the processing space 172, the by-products may descend and move onto the sealing plate 100 and the sealing rings 124. In this case, in a comparative embodiment, the sealing rings 124 may not be closely attached to a lower end of the outer tube 138 due to the by-products on the sealing rings 124 during a subsequent process (or a subsequent deposition process). Thus, in the comparative embodiment, defects in the subsequent deposition process may be caused, thereby inducing defects of semiconductor devices. However, according to embodiments of the disclosure, the gas spraying device 114 may spray the purge gas toward the sealing rings 124 through the spray pipeline 102 after the sealing plate 100 is lowered to provide the boat 130 at a lower side of the process tube 142. Accordingly, the by-products on the sealing rings 124 may be minimized or removed. As a result, defects in a subsequent deposition process may be minimized or prevented.

The regulator 108 may be configured to regulate a pressure of the purge gas, and the pressure of the purge gas may be regulated depending on an amount and a type of the by-products on the sealing rings 124. In addition, the substrate processing apparatus 10 may be configured to proceed to a subsequent operation after a specific stabilization time elapses following ejection of the purge gas.

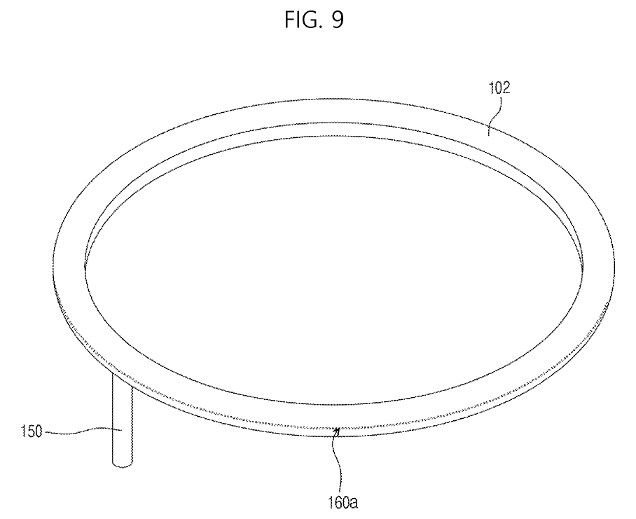

FIG. 9 is a perspective view illustrating a spray pipeline and a vertical pipeline of a substrate processing apparatus according to an embodiment of the disclosure.

Referring to FIG. 9, a plurality of spray openings 160a may be provided in the spray pipeline 102, may be arranged along the spray pipeline 102, and may be spaced apart from each other. Each of the plurality of spray openings 160a may face the sealing rings 124. The gas spraying device 114 may spray the purge gas toward the sealing rings 124 through the spray pipeline 102 having the plurality of spray openings 160a. Accordingly, the by-products on the sealing rings 124 may be minimized or removed.

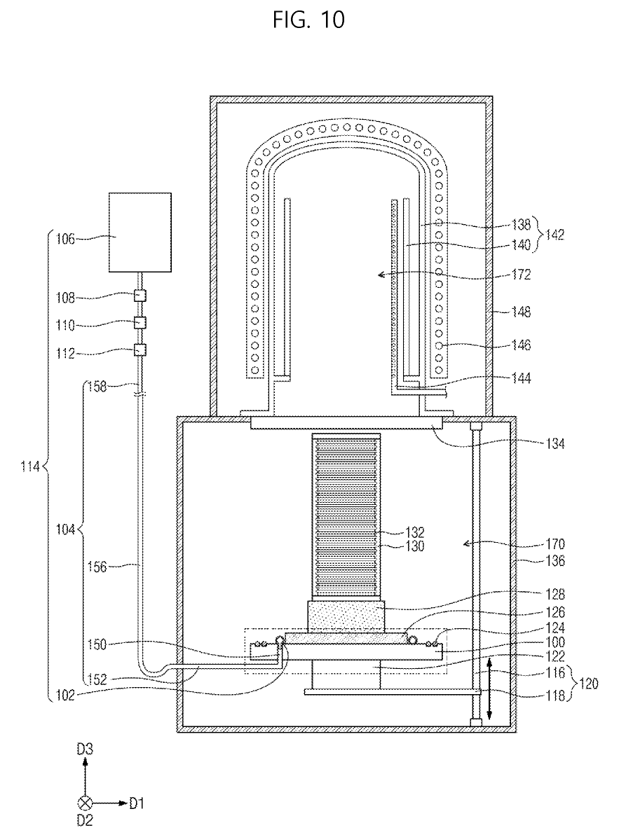

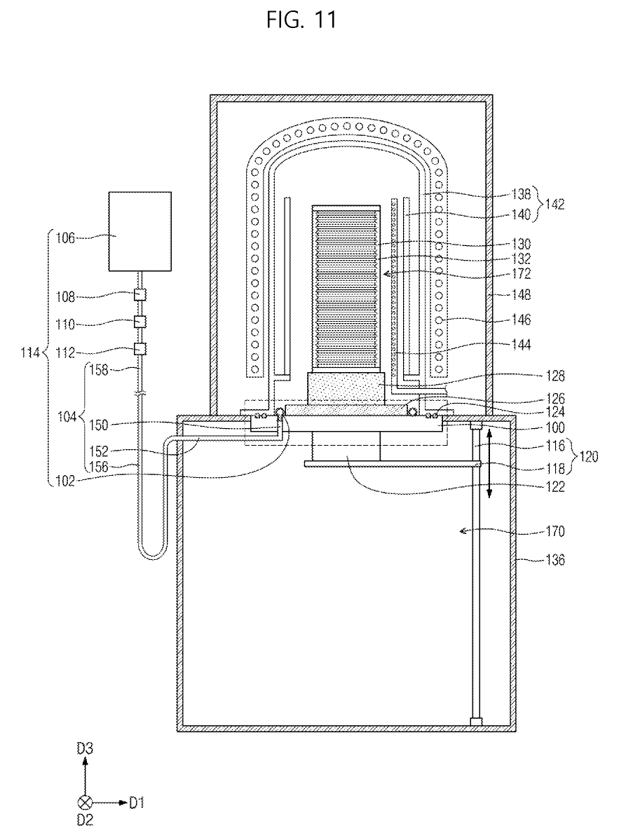

FIG. 10 is a cross-sectional view schematically illustrating a substrate processing apparatus in a first state according to an embodiment of the disclosure. FIG. 11 is a cross-sectional view schematically illustrating a substrate processing apparatus in a second state according to an embodiment of the disclosure.

Referring to FIGS. 10 and 11, the connection pipeline 104 may include a flexible pipeline 156. More specifically, one end of the vertical pipeline 150 may be coupled to the spray pipeline 102 and may pass through the sealing plate 100. One end of the first pipeline 152 may be coupled to an opposite end of the vertical pipeline 150. The first pipeline 152 may extend to the outside of the load lock chamber 136. One end of the flexible pipeline 156 may be coupled to an opposite end of the first pipeline 152. One end of the second pipeline 158 may be coupled to an opposite end of the flexible pipeline 156, and an opposite end of the second pipeline 158 may be coupled to the gas storage 106.

The flexible pipeline 156 may have flexibility, so that a shape of the flexible pipeline 156 may be freely deformable. Thus, even when the sealing plate 100 and the vertical pipeline 150 are lifted, a shape of the flexible pipeline 156 may be freely deformed so that a connection between the gas storage 106 and the spray pipeline 102 may be stably maintained.

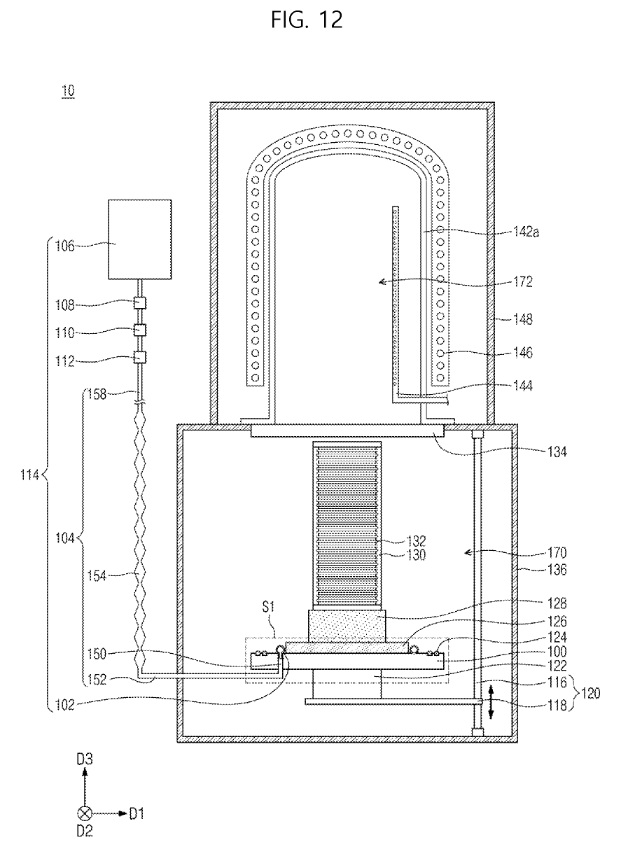

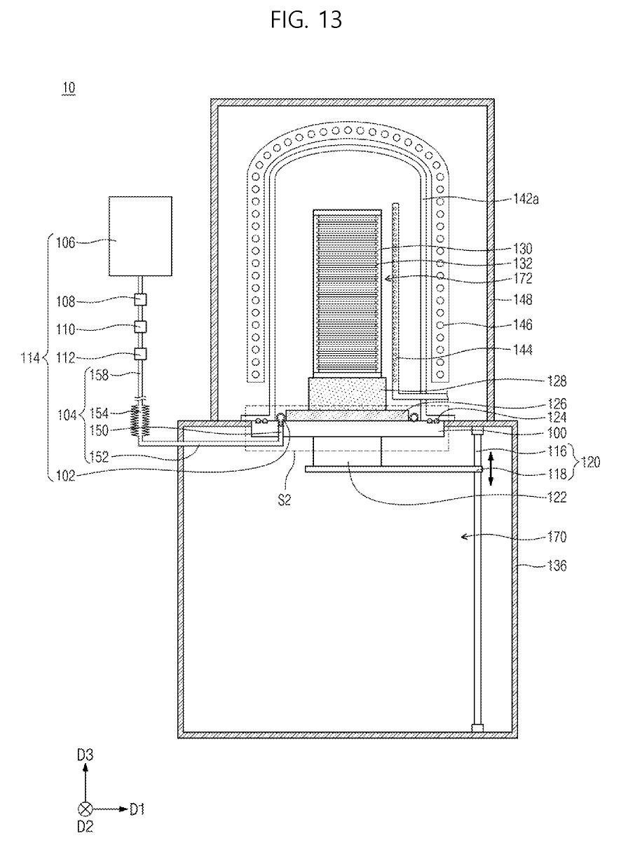

FIG. 12 is a cross-sectional view schematically illustrating a substrate processing apparatus in a first state according to an embodiment of the disclosure. FIG. 13 is a cross-sectional view schematically illustrating a substrate processing apparatus in a second state according to an embodiment of the disclosure.

Referring to FIGS. 12 and 13, in some embodiments, a process tube 142a may be formed as a single tube. The process tube 142a may have a cylindrical shape that extends in the third direction D3. The process tube 142a may have an opened lower end. A ceiling part of the process tube 142a may have a dome shape. As illustrated in FIG. 12, a process nozzle 144 may be located in the process tube 142a.

In some embodiments, a lower end of the process tube 142a may include a portion that extends flat in the first direction D1. As illustrated in FIG. 13, in the second state, the sealing rings 124 of the substrate processing apparatus 10 may contact a flatly extended portion of a lower end of the process tube 142a, and may be closely attached to the flatly extended portion. In this case, the processing space 172 in the process tube 142a may be sealed by the sealing plate 100 that closes the lower end of the process tube 142a, and the sealing rings 124 that contact the lower end of the process tube 142a.

According to some embodiments, a method performed by the substrate processing apparatus 10 may be provided. The method may include loading the boat 130, including the at least one substrate 132, into the process tube 142 (or the process tube 142a); performing a process on the at least one substrate 132, within the boat 130, while the boat 130 is in the process tube 142; unloading the boat 130, including the at least one substrate 132, from the process tube 142; and spraying, by the gas spraying device 114, the gas towards the sealing rings 124 while the boat 130 is outside of the process tube 142.

For example, the loading may include: lifting, by the vertical driving device 120, the base 122, the sealing plate 100, the sealing ring 124, the protection plate 126, the temperature maintenance device 128, and the boat 130 from the load lock chamber 136 and towards the process tube 142 such that the boat 130 enters the process tube 142 and the sealing plate 100 seals the lower end of the process tube 142.

For example, the performing the process may include: performing a deposition process on the at least one substrate 132 by the heating device 146 heating the processing space 172 and the at least one process nozzle 144 supplying the process gas into the processing space 172.

For example, the unloading may include lowering, by the vertical driving device 120, the base 122, the sealing plate 100, the sealing ring 124, the protection plate 126, the temperature maintenance device 128, and the boat 130 such that the boat 130 exits the process tube 142 and enters the load lock chamber 136.

For example, the spraying may include: removing by-products on the sealing rings 124 by spraying, by the gas spraying device 114, the purge gas.

According to some embodiments, the operations of the method may be repeated.

According to some embodiments, the substrate processing apparatus 10 may further include a controller configured to control one or more (e.g., some or all) of other components of the substrate processing apparatus 10 to perform their respective functions. For example, the controller may be configured to control the vertical driving device 120, the shutter 134, the process nozzle 144, the heating device 146, and the gas spraying device 114, etc., and one or more (e.g., some or all) subcomponents thereof, to perform their respective functions. For example, the controller may control the substrate processing apparatus 10 to perform methods according to embodiments of the disclosure.

According to some embodiments, the controller may include at least one processor and memory storing computer instructions. The computer instructions, when executed by the at least one processor, may be configured to cause the controller to perform its functions.

According to embodiments of the disclosure, the spray pipeline coupled to an upper surface of the sealing plate may have a spray opening that faces at least one sealing ring. Accordingly, the purge gas may be sprayed toward the at least one sealing ring through the spray opening of the spray pipeline. As a result, the by-products on the at least one sealing ring may be minimized or removed. Accordingly, the sealing performance between the process tube and the at least one sealing ring may be optimized.

According to embodiments of the disclosure, the gas spraying device may include the spray pipeline coupled to the upper surface of the sealing plate. The gas spraying device may be configured to spray the purge gas toward the at least one sealing ring through the spray pipeline. As a result, the by-products on the at least one sealing ring may be minimized or removed. Accordingly, the sealing performance between the process tube and the at least one sealing ring may be optimized.

Non-limiting example embodiments of the disclosure have been described above with reference to the accompanying drawings. It will be apparent to those of ordinary skill in the art that various changes and modifications may be made to the example embodiments without departing from the spirit and scope of the disclosure. Thus, the various changes and modifications of the example embodiments are included within the spirit and scope of the disclosure.

What is claimed is:

1. A substrate processing apparatus comprising:
a process tube including an opened lower end;
a sealing plate at a lower side of the process tube;
a boat on an upper side of the sealing plate in a first direction, the boat configured to accommodate a plurality of substrates;
at least one sealing ring connected to an upper surface of the sealing plate; and
a spray pipeline on the upper surface of the sealing plate,
wherein the spray pipeline includes at least one spray opening that faces the at least one sealing ring, and the spray pipeline is configured to spray a fluid, via the at least one spray opening, towards the at least one sealing ring.

2. The substrate processing apparatus of claim 1, wherein the spray pipeline has a closed loop shape, and the closed loop shape surrounds the boat in a plan view.

3. The substrate processing apparatus of claim 1, wherein the spray pipeline is between the boat and the at least one sealing ring in a second direction that crosses the first direction.

4. The substrate processing apparatus of claim 1, wherein the at least one spray opening includes single slit shape that extends along the spray pipeline, and
wherein a total length of the single slit shape is the same as a total length of the spray pipeline.

5. The substrate processing apparatus of claim 1, wherein the at least one spray opening comprises a plurality of spray openings, and
wherein the plurality of spray openings are arranged along the spray pipeline, and are spaced apart from each other.

6. The substrate processing apparatus of claim 1, further comprising:
a gas storage;
a connection pipeline connecting the gas storage to the spray pipeline;
a regulator connected to the connection pipeline, and configured to regulate a pressure of gas in the connection pipeline; and
a gas valve connected to the connection pipeline.

7. The substrate processing apparatus of claim 6, wherein the connection pipeline comprises a pipeline that has a variable length.

8. The substrate processing apparatus of claim 6, wherein the connection pipeline comprises a flexible pipeline.

9. The substrate processing apparatus of claim 6, wherein the connection pipeline comprises a vertical pipeline that vertically passes through the sealing plate.

10. The substrate processing apparatus of claim 1, wherein the sealing plate is configured to be lifted such that the boat enters the process tube and the sealing plate closes a lower end of the process tube, and
wherein the sealing plate is configured to be lowered such that the boat exits the process tube at a lower side of the process tube.

11. The substrate processing apparatus of claim 10, wherein the spray pipeline is configured to enter the process tube based on the sealing plate being lifted and closing the lower end of the process tube.

12. The substrate processing apparatus of claim 1, further comprising:
a heat absorbing material between the sealing plate and the boat, the heat absorbing material configured to regulate a temperature of the process tube; and
a protection plate between the sealing plate and the heat absorbing material, the protection plate configured to protect the sealing plate from heat.

13. A substrate processing apparatus comprising:
a process tube comprising an opened lower end;
a sealing plate at a lower side of the process tube;
a boat on an upper side of the sealing plate;
at least one sealing ring connected to an upper surface of the sealing plate; and
a gas spraying device comprising a spray pipeline, the spray pipeline being on the upper surface of the sealing plate,
wherein the gas spraying device is configured to spray purge gas toward the at least one sealing ring through the spray pipeline.

14. The substrate processing apparatus of claim 13, wherein the spray pipeline includes at least one spray opening that faces the at least one sealing ring.

15. The substrate processing apparatus of claim 13, wherein the at least one sealing ring is an O-ring, and
wherein the spray pipeline has a ring shape that surrounds the boat in a plan view.

16. The substrate processing apparatus of claim 13, wherein the sealing plate comprises a circular shape in a plan view,
wherein the at least one sealing ring has a circular ring shape in the plan view,
wherein the spray pipeline has a circular ring shape in the plan view,
wherein a center of the sealing plate coincides with a center of the at least one sealing ring and a center of the spray pipeline in the plan view, and
wherein a distance from the center of the sealing plate to the at least one sealing ring is greater than a distance from the center of the sealing plate to the spray pipeline.

17. The substrate processing apparatus of claim 13, wherein the sealing plate is configured to be lifted such that the boat enters the process tube and the sealing plate closes a lower end of the process tube,
wherein the sealing plate is configured to be lowered such that the boat exits the process tube at a lower side of the process tube, and
wherein the gas spraying device is configured to spray the purge gas while the boat is at the lower side of the process tube.

18. A substrate processing apparatus comprising:
a process tube comprising an opened lower end;
a sealing plate at a lower side of the process tube;
a boat on an upper side of the sealing plate, the boat configured to accommodate a plurality of substrates;
a heat absorbing material between the sealing plate and the boat, the heat absorbing material configured to regulate a temperature of the process tube;
a protection plate between the sealing plate and the heat absorbing material, the protection plate configured to protect the sealing plate from heat;
at least one actuator configured to vertically move the sealing plate;
at least one sealing ring connected to an upper surface of the sealing plate; and
a spray pipeline on the upper surface of the sealing plate,
wherein the spray pipeline includes at least one spray opening that faces the at least one sealing ring, and the spray pipeline is configured to spray a fluid, via the at least one spray opening, towards the at least one sealing ring.

19. The substrate processing apparatus of claim 18, further comprising:
a gas storage; and
a connection pipeline comprising a variable length,
wherein the connection pipeline connects the gas storage to the spray pipeline.

20. The substrate processing apparatus of claim 18, further comprising:
a gas storage; and
a connection pipeline comprising a flexible pipeline,
wherein the connection pipeline connects the gas storage to the spray pipeline.
